(19) United States
(12) Patent Application Publication
(10) Pub. No.: US 2004/0232552 A1
(43) Pub. Date: Nov. 25, 2004

(54) Air gap dual damascene process and structure

(75) Inventors: Fei Wang, San Jose, CA (US); Lynne A. Okada, Sunnyvale, CA (US)

Correspondence Address: MCDERMOTT, WILL & EMERY, 600 13th Street, N.W., Washington, DC, 20005-3096, US

(73) Assignee: Advanced Micro Devices, Inc.

(21) Appl. No.: 10/314,151

(22) Filed: Dec. 9, 2002

(51) Int. Cl. H01L 23/48

(52) U.S. Cl. 257/758

(57) ABSTRACT

A dual damascene air gap process reduces the dielectric constant, and extends CVD low-k technology by removing the sacrificial intra-metal dielectric between conductive lines by patterned etching and replacement with lower k material. The void space between the narrowly spaced conductive lines is sealed in by the non-conformal CVD deposition, thereby further reducing the overall capacitance of the dual damascene interconnect formation.

### FIELD OF THE INVENTION

The present invention relates to the formation of the interconnect structures in semiconductor processing, and more particularly, to the formation of a dual damascene interconnect structure.

### BACKGROUND OF THE INVENTION

The escalating requirements for high-density and performance associated with ultra large-scale integration semiconductor wiring require responsive changes in interconnection technology. Such escalating requirements have been found difficult to satisfy in terms of providing a low RC (resistance capacitance) interconnection pattern, particularly where sub-micron via contacts and trenches have high aspect ratios imposed by miniaturization.

Conventional semiconductor devices typically comprise a semiconductor substrate, normally of doped monocrystalline silicon, and a plurality of sequentially formed dielectric layers and conductive patterns. An integrated circuit is formed containing a plurality of conductive patterns comprising conductive lines separated by inter-wiring spacings. Typically, the conductive patterns on different layers, i.e., upper and lower layers, are electrically connected by a conductive plug filling a via hole, while a conductive plug filling a contact hole establishes electrical contact with an active region on a semiconductor substrate, such as a source/drain region. Conductive lines are formed in trenches which typically extend substantially horizontal with respect to the semiconductor substrate. Semiconductor chips comprising five or more levels of metallization are becoming more prevalent as device geometries shrink to sub-micron levels.

A conductive plug filling a via hole is typically formed by depositing a dielectric interlayer on a conductive layer comprising at least one conductive pattern, forming an opening in the dielectric layer by conventional photolithographic and etching techniques, and filling the opening with a conductive material, such as tungsten (W). Excess conductive material on the surface of the dielectric layer is typically removed by chemical mechanical polishing (CMP). One such method is known as damascene and basically involves forming an opening in the dielectric interlayer and filling the opening with a metal. Dual damascene techniques involve forming an opening comprising a lower contact or via hole section in communication with an upper trench section, which opening is filled with a conductive material, typically a metal, to simultaneously form a conductive plug and electrical contact with a conductive line.

High-performance microprocessor applications require rapid speed of semiconductor circuitry. The control speed of semiconductor circuitry varies inversely with the resistance and capacitance of the interconnect pattern. As integrated circuits become more complex and feature sizes and spacings become smaller, the integrated circuit speed becomes less dependent upon the transistor itself and more dependent upon the interconnection pattern. Miniaturization demands long interconnects having small contacts and small cross-sections. Thus, the interconnection pattern limits the speed of the integrated circuit. If the interconnection node is routed over a considerable distance, e.g., hundreds of microns or more as in sub-micron technologies, the interconnection capacitance limits the circuit node capacitance loading, and hence, the circuit speed. As integration density increases and feature size decreases in accordance with sub-micron design rules, e.g., a design rule of about 0.1 micron and below, the rejection rate due to integrated circuit speed delays severely limits production throughput and significantly increases manufacturing costs.

In prior technologies, aluminum was used in very large scale integration interconnect metallization. Copper and copper alloys have received considerable attention as a candidate for replacing aluminum in these metallizations. Copper has a lower resistivity than aluminum and improved electrical properties compared to tungsten, making copper a desirable metal for use as a conductive plug as well as conductive wiring.

In the formation of a dual damascene structure in a self-aligned manner, a conductive line and vias that connect the line to conductive elements in a previously formed underlying conductive layer, are simultaneously deposited. A conductive material is deposited into openings (e.g., the via holes and trenches) created in dielectric material that overlays the conductive interconnect layer. Typically, a first layer of dielectric material is deposited over a bottom etch stop layer that covers and protects the conductive interconnect layer. A middle etch stop layer is then deposited over the first dielectric layer. A pattern is then etched into the middle etch stop layer to define the feature, such as a via hole, that will later be etched into the first dielectric layer. Once the middle etch stop layer is patterned, a second dielectric layer is deposited on the middle etch stop layer. The hard mask layer may then be deposited on the second dielectric layer. A desired feature, such as a trench, is etched through the hard mask layer and the second dielectric layer. This etching continues so that the first dielectric layer is etched in the same step as the second dielectric layer. The etching of the two dielectric layers in a single etching step reduces the number of manufacturing steps. The bottom etch stop layer within the via hole, which has protected the conductive material in the conductive interconnect layer, is then removed with a different etchant chemistry. With the via holes now formed in the first dielectric layer and a trench formed in the second dielectric layer, conductive material is simultaneously deposited in the via and the trench in a single deposition step. (If copper is used as the conductive material, a barrier layer is conventionally deposited first to prevent copper diffusion.) The conductive material makes electrically conductive contact with the conductive material in the underlying conductive interconnect layer.

There is a continuous need to lower the capacitance of a metal interconnect structure. In certain structures, a sacrificial intra-metal dielectric is removed by patterned etching and is replaced by lower k material. Other methods of lowering the dielectric constant is by sealing void spaces between narrowly spaced lines using non-conformal CVD depositions. However, the use of such techniques have not been applied to dual damascene structures, such as those structures described above.

### SUMMARY OF THE INVENTION

There is a continued need for reducing the capacitance in dual damascene formations in interconnect structures.

These and other needs are met by embodiments of the present invention which provide a method of forming a dual damascene structure comprising the steps of forming first conductive structures on a substrate, with sacrificial material separating the first conductive structures. The sacrificial material is removed to form recesses between the first conductive structures. Dielectric material is non-conformally deposited over the first conductive structures and in the recesses, such that an air gap is formed within the dielectric material in the recesses. A sacrificial layer is then formed over the dielectric material. A dual damascene recess is etched into the sacrificial layer and the dielectric material. The dual damascene recess is filled with conductive material to form a second conductive structure.

Some of the advantages of the present invention include the integration of the formation of air gaps between trench lines in dual damascene structures. This leads to lower capacitance in the entire metal interconnect structure. A reduced capacitance in the metal interconnect structure provides better overall device performance. In addition, in certain embodiments of the invention, the sacrificial material is replaced with a low-k dielectric material to further lower the dielectric constant of the formation.

The earlier stated needs are also met by other embodiments of the present invention which provide a dual damascene interconnect structure comprising copper lines formed on the substrate, the copper lines being separated from each other by spaces. A non-conformal dielectric material is in the spaces and over the copper lines. Air gaps are present within the dielectric material that is in spaces. A dielectric layer is formed over the dielectric material. A dual damascene recess is formed in the dielectric layer and the dielectric material, with copper fill being provided in the dual damascene recess.

The foregoing and other features, aspects and advantages of the present invention will become more apparent from the following detailed description of the present invention when taken into conjunction with the accompanying drawings.

### BRIEF DESCRIPTION OF THE DRAWINGS

FIG. 1 is a schematic depiction of a cross-section of an interconnect formation during one phase of the processing sequence in accordance with embodiments of the present invention.

FIG. 2 shows the structure of FIG. 1 following the etching of a sacrificial layer in accordance with embodiments of the present invention.

FIG. 3 shows the structure of FIG. 2 following a fill process, annealing and planarization steps in accordance with embodiments of the present invention.

FIG. 4 depicts the structure of FIG. 3 following the deposition of a selective barrier material on the conductive lines.

FIG. 5 shows the structure of FIG. 4 following the removal of sacrificial material within the recesses between the conductive lines, in accordance with embodiments of the present invention.

FIG. 6 depicts the structure of FIG. 5 after a resist mask is patterned to open the dense areas, and a dielectric material has been non-conformally deposited in accordance with embodiments of the present invention.

FIG. 7 shows the structure of FIG. 6 after a sacrificial removal stop layer, sacrificial layer, and cap layer are deposited over the non-conformally deposited dielectric material in accordance with embodiments of the present invention.

FIG. 8 depicts the structure of FIG. 7 after a trench and a via hole are etched through the cap layer, sacrificial layer, and sacrificial removal stop layer, in accordance with embodiments of the present invention.

FIG. 9 shows the structure of FIG. 8 after a fill process has been performed to form a conductive plug and conductive line, in accordance with embodiments of the present invention.

FIG. 10 schematically depicts a cross-section of a portion of an interconnect structure constructed in accordance with another embodiment of the present invention, during one step of manufacture.

FIG. 11 shows the structure of FIG. 10 after a sacrificial layer has been stripped in accordance with methods of the present invention.

FIG. 12 depicts the structure of FIG. 11 following the stripping of resist and non-conformal deposition of a sealing material, in accordance with embodiments of the present invention.

FIG. 13 shows the structure of FIG. 12, after the non-conformal deposition of a dielectric material, in accordance with embodiments of the present invention.

FIG. 14 shows the structure of FIG. 13 following the etching of recesses into the non-conformally deposited dielectric material, and the removal of the resist, in accordance with embodiments of the present invention.

FIG. 15 shows the structure of FIG. 14, after the fill process is performed to form the interconnect structures in accordance with embodiments of the present invention.

FIGS. 16a-16c show an air gap dual damascene process with resist patterning in accordance with embodiments of the present invention.

FIGS. 17a-17d show an air gap dual damascene process without resist patterning in accordance with embodiments of the present invention.

### DETAILED DESCRIPTION OF THE INVENTION

The present invention addresses problems related to the formation of dual damascene interconnects, including that of lowering the dielectric constant of such formations. These problems are solved, in part, by the present invention employing sacrificial material to form recesses between the conductive lines formed on a substrate. The sacrificial material is removed and replaced with low-k dielectric material, for example. Low-k dielectric material, or other type of dielectric material, is non-conformally deposited over the conductive lines and in the recesses in a manner such that an air gap is formed within the dielectric material within the recesses. This lowers the overall dielectric constant of the formation even further. A sacrificial layer is formed over the dielectric material, and a dual damascene recess is etched into the sacrificial layer and the dielectric material. This dual damascene recess is filled with conductive material to form an interconnect structure connected to the underlying conductive lines. These steps can be repeated in order to form higher levels of metallization with dual damascene structures.

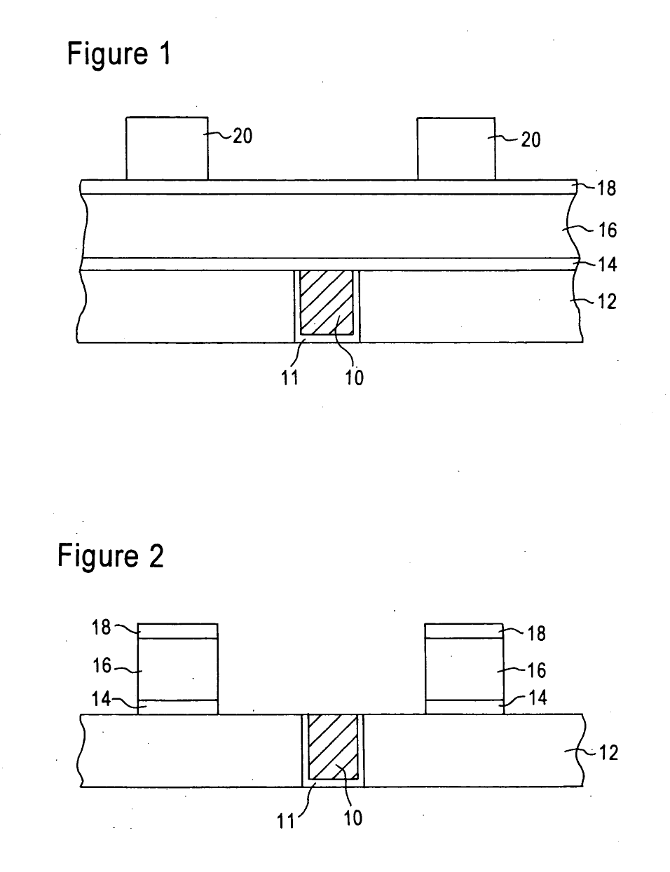

FIG. 1 is a schematic depiction of a cross-section of a portion of a metal interconnect formation during one phase of processing in accordance with embodiments of the present invention. The arrangement includes a first copper feature 10, such as a copper line. A dielectric material 12, such as a low-k dielectric, with a first copper feature 10 forms a metallization layer. A barrier layer 11, such as Ta, TaN, TiSiN, TiN, WCN, etc., lines the recess and prevents diffusion of copper from the copper feature. Examples of low-k dielectric materials, which provide advantages in reducing the overall capacitance of a device, may be any of a number of different types of low-k dielectric materials, such as inorganic or organic dielectric materials. A sacrificial removal stop layer 14 is formed over the dielectric layer 12 and the first copper feature 10. The sacrificial removal stop layer 14 may be made of Blok for example, a dielectric constant material that may serve as stop layer when oxide-based material is being etched. A sacrificial material, such as an oxide derived from tetraethyl orthosilicate (TEOS), forming a sacrificial layer 16, is deposited on the sacrificial removal stop layer 14. As will be described, other embodiments of the invention use other materials for the sacrificial layer 16. Also, depending upon the sacrificial material in the sacrificial layer 16 that is employed, different materials may be employed in the sacrificial removal stop layer 14. For purposes of the following descriptive exemplary embodiment, it is assumed that the sacrificial removal stop layer comprises oxide.

A second sacrificial removal stop layer 18 is formed on the sacrificial layer 16. A photoresist 20 is deposited and patterned on the second sacrificial removal stop layer 18.

An etching is then performed, the results of which are depicted in FIG. 2. The resist 20 has been removed by photoresist stripping.

In certain embodiments of the invention, the sacrificial materials in the sacrificial layer 16 are silicon dioxide based (SiO₂-based), such as oxide, methyl silsesquioxane (MSQ), spin-on glass (SOG) hydrogen silsesquioxane (HSQ), etc. In such embodiments, the sacrificial stop layers 14, 18 may comprise material such as silicon nitride (SiN), silicon carbide (SiC) or an organic layer. The removal of the sacrificial material in the sacrificial layer 16 employs etchant chemistry suitable for etching the sacrificial material and stopping on the sacrificial removal stop layer 14. Suitable etchant chemistries include HF, or a BoE dip.

In other embodiments of the invention, the sacrificial material on the sacrificial layer 16 includes organic materials, such as SiLK, P-SiLK etc. The stop layer may be made of oxide, or no sacrificial removal stop layer 14 can be provided. The sacrificial material 16 is removed by O₂/N₂ plasma, for example.

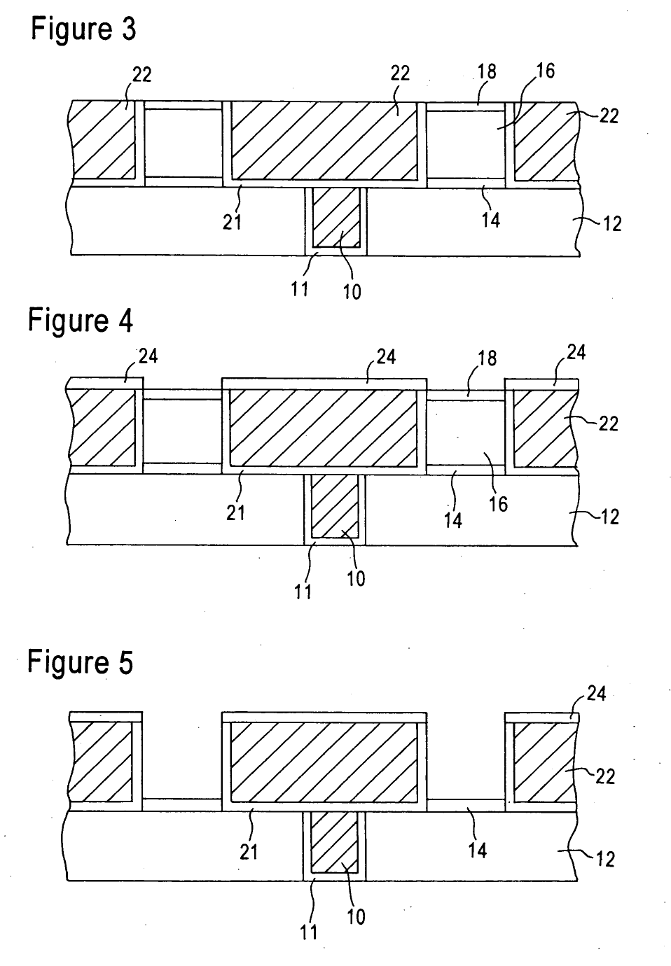

Following the etching, a copper fill process is performed to fill the recesses with copper. Conventional copper-fill processes may be employed including the use of barrier layers 21 to prevent diffusion of the copper. The same materials may be used as in the barrier layer 11. These structures will be referred to as first conductive structures 22 in the following description. Although copper has been described as forming the first conductive structures 22, other materials may be employed without departing from the spirit or scope of the present invention. Following the filling of the copper and the creation of the first conductive structures 22, conventional annealing and planarization (e.g., chemical mechanical polishing) steps may be performed to create the structure of FIG. 3.

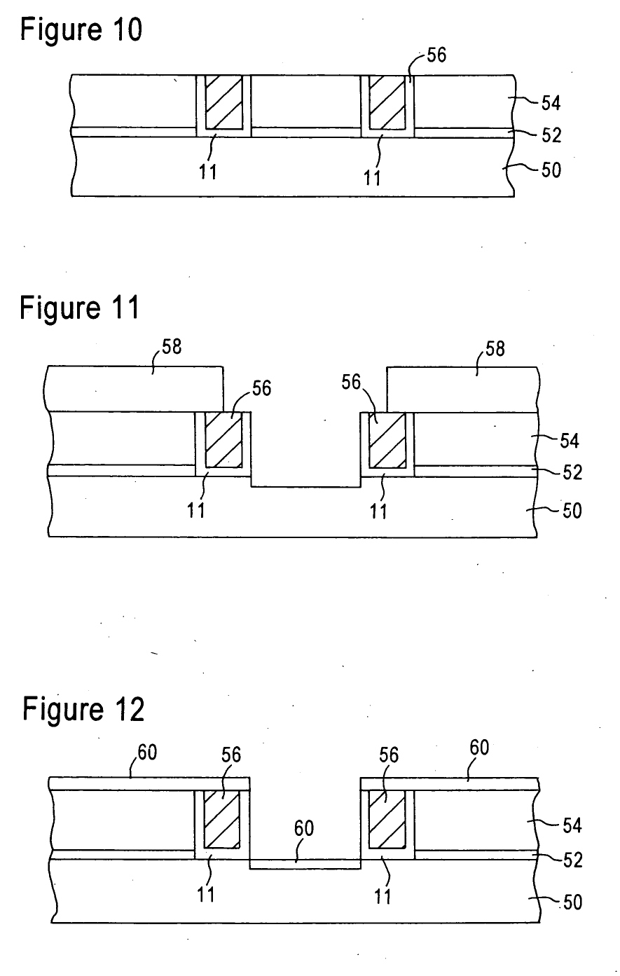

As shown in FIG. 4, a barrier metal such as CoWP, W, CoWB etc., is selectively deposited by electroless deposition on the top surfaces of the first conductive structures 22. The barrier material 24 seals the surfaces of the copper in the first conductive structures 22. If a selective barrier material is not available, the sacrificial layer 16 can be stripped, followed by a non-conformal deposition silicon carbide or silicon nitride to seal the copper in the first conductive structures 22. This embodiment will be described with respect to FIGS. 10-15.

In FIG. 5, the sacrificial layer 18 has been removed between the first conductive structures 22. The etching stops at the sacrificial removal stop layer 14. Exemplary etchants were previously described for various sacrificial materials and stop layers. The removal of the sacrificial material is performed by etching following the formation of a resist mask to open the dense areas only. Following the removal of the sacrificial material in the sacrificial layer 16, a dielectric material is non-conformally deposited over the first conductive structure 22. In certain embodiments of the invention, the dielectric material 26 is deposited by chemical vapor deposition (CVD) in a non-conformal manner. The dielectric material 26, in further embodiments of the invention, is a low-k dielectric material. The thickness of the dielectric material 26 over the barrier material 24 should be the same thickness as the desired feature that will be formed above the barrier material 24. For example, if a via or conductive plug is to be formed over the first conductive structures 22, the CVD low-k dielectric material 26 should have the same thickness as the desired height of the conductive plug.

The non-conformal depositing of the CVD low-k dielectric material 26 creates air gaps 28 between the first conductive structures 22. These air gaps 28 lower the dielectric constant and reduce the overall capacitance.

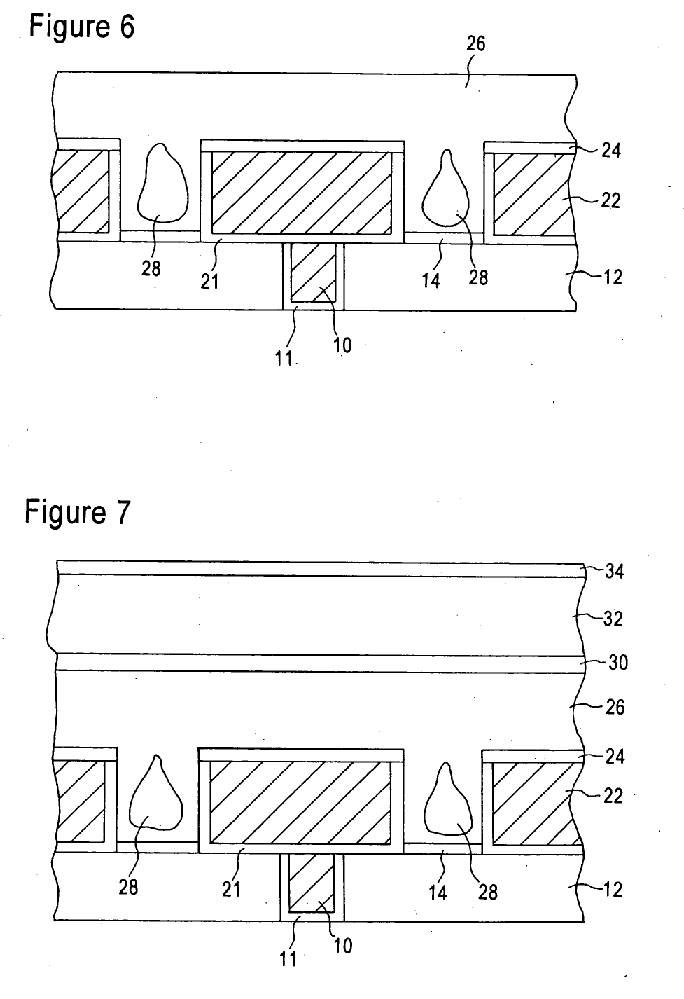

FIG. 7 shows the structure of FIG. 6 following the deposition of another sacrificial removal stop layer 30, another sacrificial layer 32, and a cap layer 34.

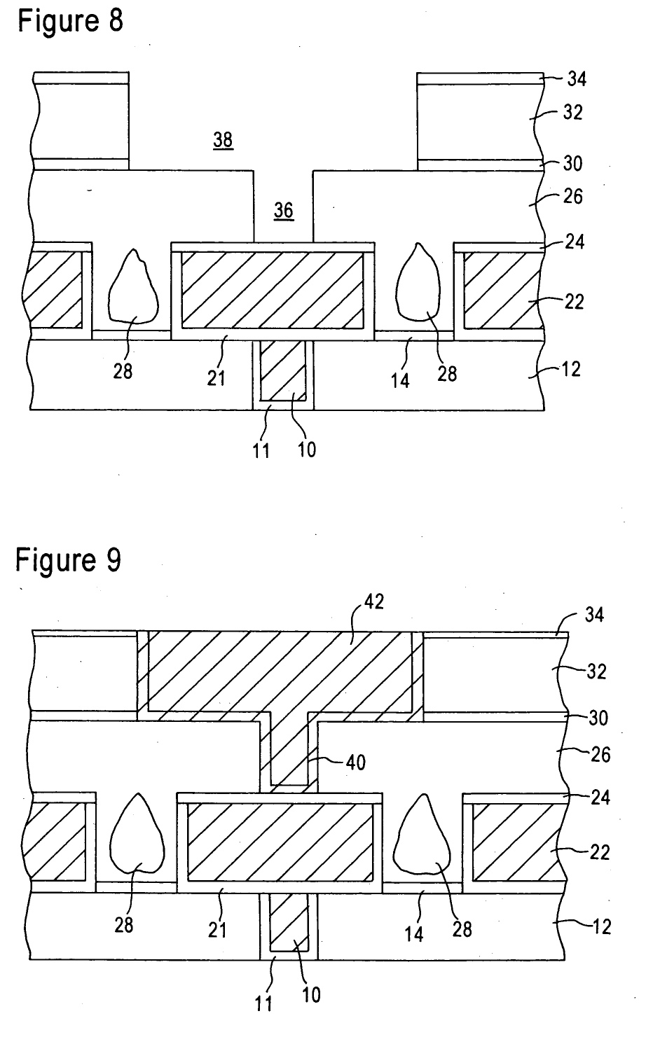

In FIG. 8, a dual damascene etching has been performed to create a via hole 36 and a trench 38. The etching is performed in accordance with conventional etching techniques to create the via hole 36 and trench 38.

A copper-fill process, when the conductive material is copper, is performed, as shown in FIG. 9, to create a conductive plug 40 with a conductive line 42. The conductive plug 40 and the conductive line 42 may be considered to form a second conductive structure.

Following the formation of the second conductive structure (40, 42), the above-described process may be repeated such that the sacrificial material between the conductive lines 42 in the sacrificial layer 32 is replaced by low-k dielectric material, with air gaps being formed between the conductive lines 42. Hence, the non-conformal CVD deposition creates the air gaps between the conductive lines of dual damascene structures so that the overall capacitance of the structure may be lowered in accordance with embodiments of the present invention. This process may be repeated on the different metallization levels.

As briefly mentioned earlier, FIGS. 10-15 describe an alternative embodiment in which a selective barrier material is not employed. As shown in FIG. 10, a dielectric layer 50 is provided, formed of oxide, for example, derived from tetraethyl orthosilicate. A layer of silicon nitride, or other appropriate barrier material, has reference numeral 52 in FIG. 10. A layer of sacrificial material, such as oxide derived from TEOS, comprises layer 54. Conductive structures 56 have been formed in the dielectric layer 54 and through the barrier material 52.

In this embodiment, the sacrificial layer 54 is stripped, as depicted in FIG. 11. This stripping removes a portion of the substrate layer 50. The stripping is performed after a photoresist 58 has been deposited and patterned. The stripping may be formed by a plasma etch, for example.

As shown in FIG. 12, following the resist strip, a barrier material non-conformal deposition is performed. The barrier material 60 that is non-conformally deposited may be silicon nitride or silicon carbide, for example. This barrier material 60 acts to seal the copper of the conductive structure 56.

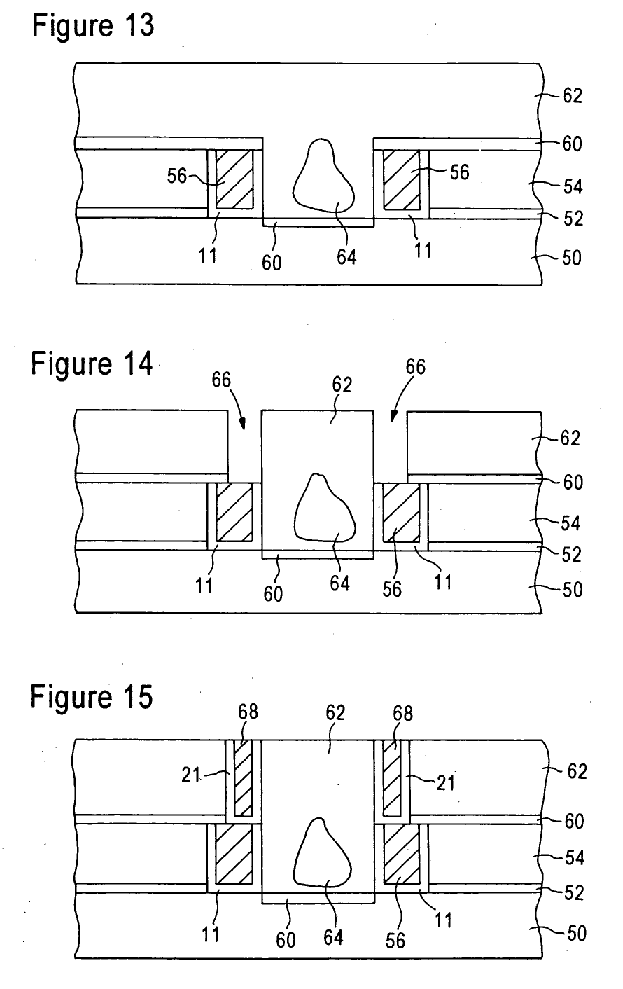

A dielectric material 62 is then non-conformally deposited, as depicted in FIG. 13. An air gap 64 between the conductive structures is created by this non-conformal deposition of the dielectric material 62. An exemplary material for the dielectric material is oxide. The non-conformal deposition may be performed by physical deposition (PVD) or chemical vapor deposition (CVD), for example.

A resist pattern is formed and etching is performed, the results of which are depicted in FIG. 14, following the removal of the resist. Resist 66 is created above the conductive structures. A copper fill process is then performed, as depicted in FIG. 15, to create the second conductive structures 68 that contact the first conductive structures 56.

Again, in this embodiment, non-conformal deposition of dielectric material between the conductive structures produces an air gap to lower the overall capacitance of the interconnect formation. Also, the removal of the sacrificial intra-metal dielectric by patterned etching allows replacement of this dielectric material with lower k material, again reducing the overall capacitance and improving device performance.

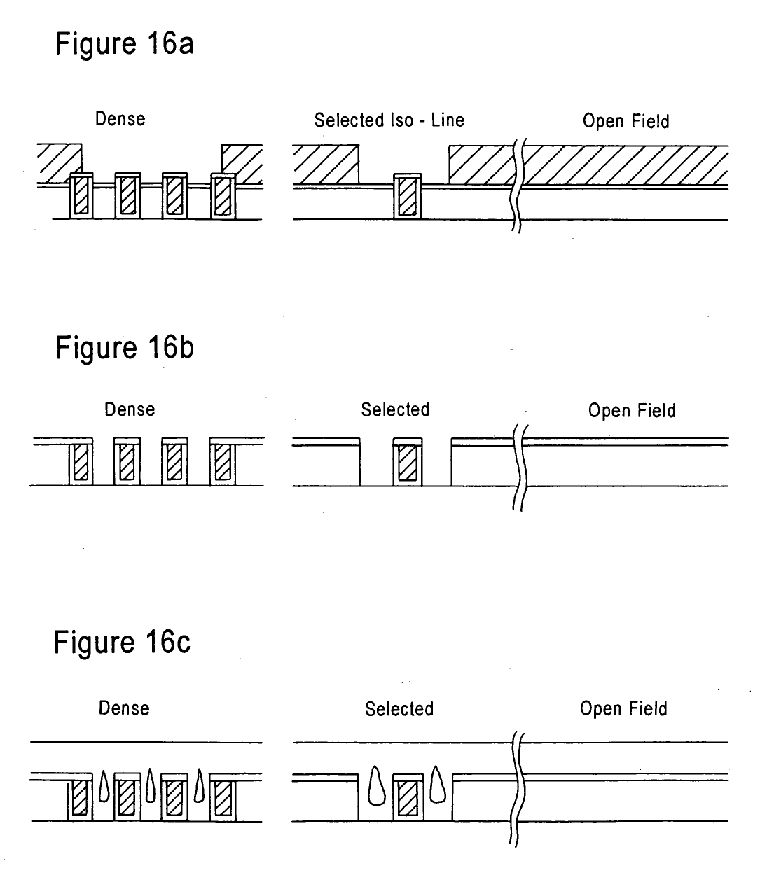

FIGS. 16a-16c depict the air gap dual damascene process in embodiments that employ resist patterning. In FIG. 16a, a dense region, a selected isolated region, and an open field area are depicted. A resist mask has been formed such that openings in the mask are provided only at the dense area and the selected isolated line. Processing proceeds as described above with respect to FIGS. 1-15, with removal of the sacrificial material and the resist, leaving the structure of FIG. 16b. This is followed by the non-conformal deposition of the low k dielectric material, as described earlier, to create the air gaps, as shown in FIG. 16c. With this embodiment, surface planarity can be maintained, and the thickness of the ILD layer on top of the copper features is uniform.

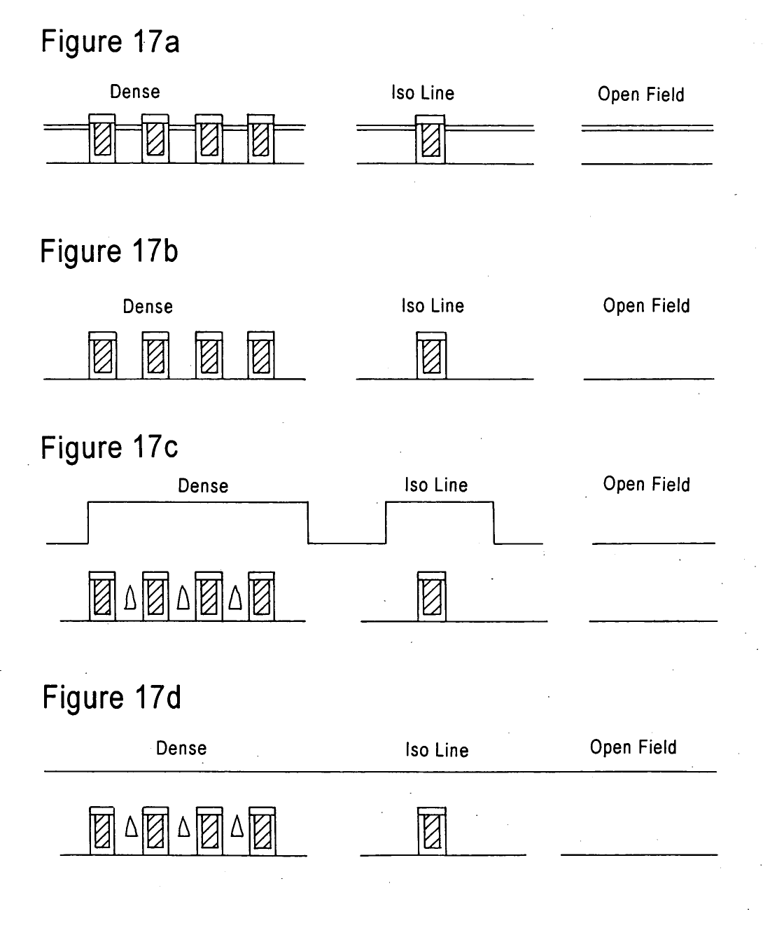

FIGS. 17a-17d depict the air gap dual damascene process in embodiments in which resist patterning is not used. Again, in each of these figures, a dense region, a selected isolated line, and an open field area are depicted, as initially seen in FIG. 17a. Sacrificial material is completely removed, as seen in FIG. 17b by etching. A non-conformal deposition of the low k dielectric material is performed, leaving a non-planarized surface, as seen in FIG. 17c. A thick layer of a low k dielectric material is needed so that planarization can be performed, the results of which are depicted in FIG. 17d. Unlike the embodiment of FIGS. 16a-16c, the area near the isolated line does not contain the air gaps that are provided in the dense region. Also, the thickness of the low k dielectric layer on the top of the copper is not necessarily uniform.

Although the present invention has been described and illustrated in detail, it is to be clearly understood that the same is by way of illustration and example only, and is not to be taken by way of limitation, the scope of the present invention being limited only by the terms of the appended claims.

What is claimed is:

1. A method of forming a dual damascene structure comprising the steps of
forming first conductive structures on a substrate, with sacrificial material separating the first conductive structures;
removing the sacrificial material to form recesses between the first conductive structures;
non-conformally depositing dielectric material over the first conductive structures and in the recesses, such that an air gap is formed within the dielectric material in the recesses;
forming a sacrificial layer over the dielectric material;
etching a dual damascene recess into the sacrificial layer and the dielectric material; and
filling the dual damascene recess with conductive material to form a second conductive structure.

2. The method of claim 1, wherein the first conductive structures and the second conductive structure comprise copper or a copper alloy.

3. The method of claim 2, wherein the dielectric material is a low k dielectric material.

4. The method of claim 3, wherein the step of non-conformally depositing dielectric material includes depositing the low-k dielectric material by chemical vapor deposition (CVD).

5. The method of claim 2, wherein the dielectric material is an oxide, and the step of non-conformally depositing dielectric material includes depositing the oxide by chemical vapor deposition.

6. The method of claim 4, further comprising selectively depositing barrier material on the first conductive structures prior to removing the sacrificial material to form recesses between the first conductive structures.

7. The method of claim 6, wherein the barrier material comprises one of: CoWP, W and CoWB.

8. The method of claim 6, further comprising forming a sacrificial removal stop layer on the substrate prior to forming the first conductive structures on the substrate.

9. The method of claim 8, wherein the sacrificial material and the sacrificial layer comprise a SiO₂-based dielectric material, and the sacrificial removal stop layer is one of: SiN, SiC, or an organic material.

10. The method of claim 9, wherein the SiO₂-based dielectric material is one of: oxide, methyl silsesquioxane (MSQ), spin-on glass (SOG); hydrogen silsesquioxane (HSQ).

11. The method of claim 8, wherein the sacrificial material and the sacrificial layer comprise an organic material and the sacrificial removal stop layer is an oxide.

12. The method of claim 6, wherein the sacrificial material and the sacrificial layer comprise an organic material.

13. The method of claim 2, further comprising non-conformally depositing a copper sealing layer on the first conductive structures after removing the sacrificial material and prior to non-conformally depositing dielectric material.

14. The method of claim 1, wherein the step of removing the sacrificial material includes forming a resist mask with mask openings formed only over dense regions and selected isolated regions, the first conductive structure being within the dense regions and the selected isolated regions.

15. The method of claim 14, further comprising removing the resist mask prior to the step of non-conformally depositing dieletric material.

16. A dual damascene interconnect structure comprising:
copper lines formed on a substrate, the copper lines being separated from each other by spaces;
a non-conformal dielectric material in the spaces and over the copper lines;
air gaps formed within the dielectric material that is in the spaces;
a dielectric layer formed over the dielectric material;
a dual damascene recess formed in the dielectric layer and the dielectric material; and
copper fill in the dual damascene recess.

17. The structure of claim 16, further comprising a selective barrier material on the copper lines.

18. The structure of claim 17, wherein the selective barrier material is one of CoWP, W, or CoWB.

19. The structure of claim 16, wherein the non-conformal dielectric material is CVD oxide.

20. The structure of claim 16, wherein the non-conformal dielectric material is a CVD low-k material.

21. The structure of claim 16, further comprising a non-conformal copper-sealing material on the copper lines.

22. The structure of claim 21, wherein the non-conformal copper-sealing material is one of: SiC or SiN.

23. The structure of claim 16, wherein the air gaps are formed within the dielectric material in the spaces between only selected ones of the copper lines.

24. The structure of claim 23, wherein the selected ones of the copper lines include the copper lines in dense regions on the substrate.
